(19) United States
(12) Patent Application Publication
(10) Pub. No.: US 2012/0196391 A1
(43) Pub. Date: Aug. 2, 2012

(54) METHOD FOR FABRICATING SEMICONDUCTOR LIGHTING CHIP

(75) Inventors: PO-MIN TU, Hukou (TW); SHIH-CHENG HUANG, Hukou (TW); YA-WEN LIN, Hukou (TW)

(73) Assignee: ADVANCED OPTOELECTRONIC TECHNOLOGY, INC., Hsinchu Hsien (TW)

(21) Appl. No.: 13/231,715

(22) Filed: Sep. 13, 2011

(30) Foreign Application Priority Data
Jan. 28, 2011 (CN) 201110028114.3

(51) Int. Cl. H01L 33/20; B82Y 40/00

(52) U.S. Cl. 438/22; 977/888; 257/E33.005

(57) ABSTRACT

A method for fabricating a semiconductor lighting chip includes steps: providing a substrate with an epitaxial layer, the epitaxial layer comprising a first semiconductor layer, a second semiconductor layer and an active layer located between the first semiconductor layer and the second semiconductor layer; dipping the epitaxial layer into an electrolyte to etch surfaces of the epitaxial layer and form a number of holes on the epitaxial layer; and forming electrodes on the epitaxial layer.

### 1. TECHNICAL FIELD

The disclosure generally relates to a method for fabricating semiconductor lighting chips.

### 2. DESCRIPTION OF RELATED ART

In recent years, due to excellent light quality and high luminous efficiency, light emitting diodes (LEDs) have increasingly been used as substitutes for incandescent bulbs, compact fluorescent lamps and fluorescent tubes as light sources of illumination devices.

The LED generally includes a lighting chip, which includes an n-type semiconductor layer, an active layer and a p-type semiconductor layer subsequently formed on a substrate. When a voltage is applied between the n-type semiconductor layer and the p-type semiconductor layer, hole-electron capture will happen at the active layer, and energy is released in the form of light. However, part of the light emitted by the active layer will be reflected by an interface between the lighting chip and the external environment, therefore reducing light extraction efficiency of the lighting chip.

Therefore, a method for fabricating a semiconductor lighting chip with satisfied light extraction efficiency is desired to overcome the above described shortcoming.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a diagram showing a first step of a method for fabricating a semiconductor lighting chip according to an embodiment of the present disclosure.

FIG. 2 is a diagram showing a second step of a method for fabricating a semiconductor lighting chip according to an embodiment of the present disclosure.

FIG. 3 is a diagram showing a third step of a method for fabricating a semiconductor lighting chip according to an embodiment of the present disclosure.

FIG. 4 is a diagram showing a fourth step of a method for fabricating a semiconductor lighting chip according to an embodiment of the present disclosure.

FIG. 5 is a diagram of the fourth step in FIG. 4, but showing in another aspect.

FIG. 6 is an isometric view of a semiconductor lighting chip, after the fourth step in FIG. 4.

FIG. 7 is a diagram showing a fifth step of a method for fabricating a semiconductor lighting chip according to an embodiment of the present disclosure.

FIG. 8 is a diagram showing a sixth step of a method for fabricating a semiconductor lighting chip according to an embodiment of the present disclosure.

### DETAILED DESCRIPTION

An embodiment of a method for fabricating semiconductor lighting chips will now be described in detail below and with reference to the drawings.

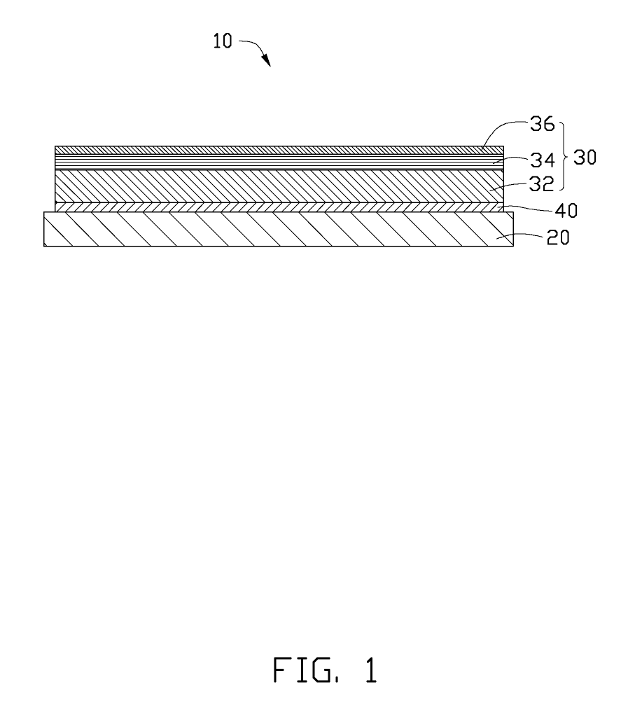

Referring to FIG. 1, a wafer 10 is firstly provided. The wafer 10 includes a substrate 20 and an epitaxial layer 30 formed on the substrate 20. Material of the substrate 20 can be selected from a group consisting of sapphire, SiC, Si, and GaN. In this embodiment, the substrate 20 is made of sapphire, and a thickness of the substrate 20 is about 430 μm. The epitaxial layer 30 is formed on the substrate 20 by metal organic chemical vapor deposition (MOCVD), molecular beam epitaxy (MBE) or hydride vapor phase epitaxy (HYPE). The epitaxial layer 30 includes a first semiconductor layer 32, an active layer 34 and a second semiconductor layer 36 subsequently grown on the substrate 20. When a voltage is applied between the first semiconductor layer 32 and the second semiconductor layer 36, hole-electron capture will happen at the active layer 34, and energy is released in the form of light. In this embodiment, the first semiconductor layer 32 is an n-type GaN layer, which has a thickness of about 4 μm. The active layer 34 is a multiple quantum well (MQW) GaN layer, which has a thickness of about 0.1 μm. The second semiconductor layer 36 is a p-type semiconductor layer, which has a thickness of about 0.125 μm. For reducing dislocation defects of the epitaxial layer 30, a buffer layer 40 is formed between the epitaxial layer 30 and the substrate 20 to reduce lattice mismatching between the epitaxial layer 30 and the substrate 20. The buffer layer 40 is made of material with a lattice constant matching that of the epitaxial layer 30. In this embodiment, the buffer layer 40 is made of AIN, which has a thickness of about 20 nm.

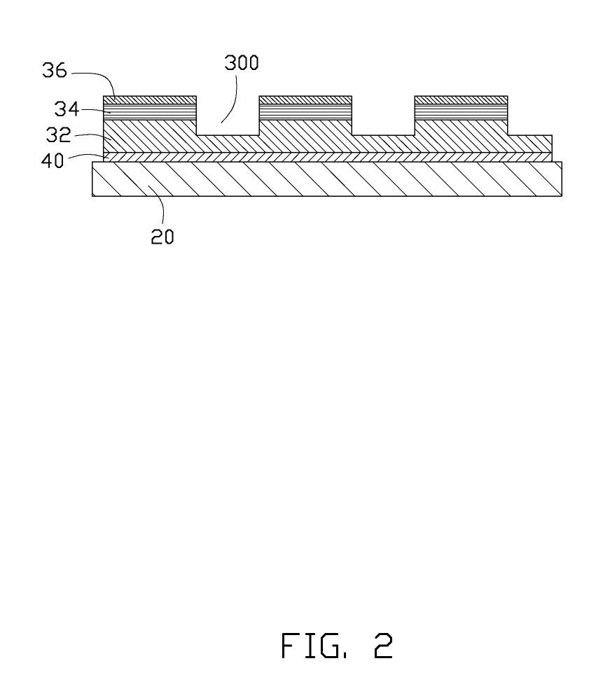

Referring to FIG. 2, etching regions are defined on an upper surface of second semiconductor layer 36 by photolithography and the etching regions are then removed to form a number of grooves 300. The grooves 300 extends from an upper surface of the second semiconductor layer 36 downward to the interior of the first semiconductor layer 32 to expose part of the first semiconductor layer 32.

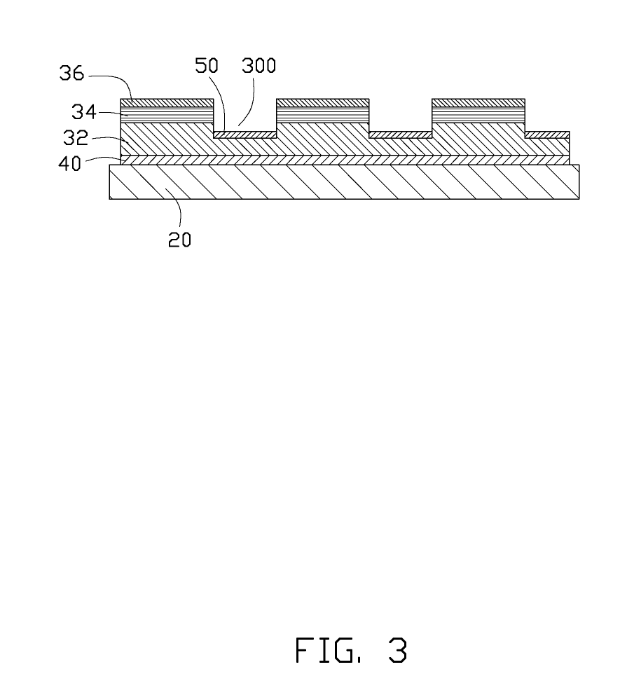

Referring to FIG. 3, a cladding layer 50 is formed on a bottom surface of each groove 300 by vacuum evaporation or sputtering, therefore covering the part of the first semiconductor layer 32 exposed to external environment. In this embodiment, the cladding layer 50 is made of SiO₂ for preventing the first semiconductor layer 32 from being etched to a rough surface in the following process. In this embodiment, an upper face of the cladding layer 50 is lower than the active layer 34.

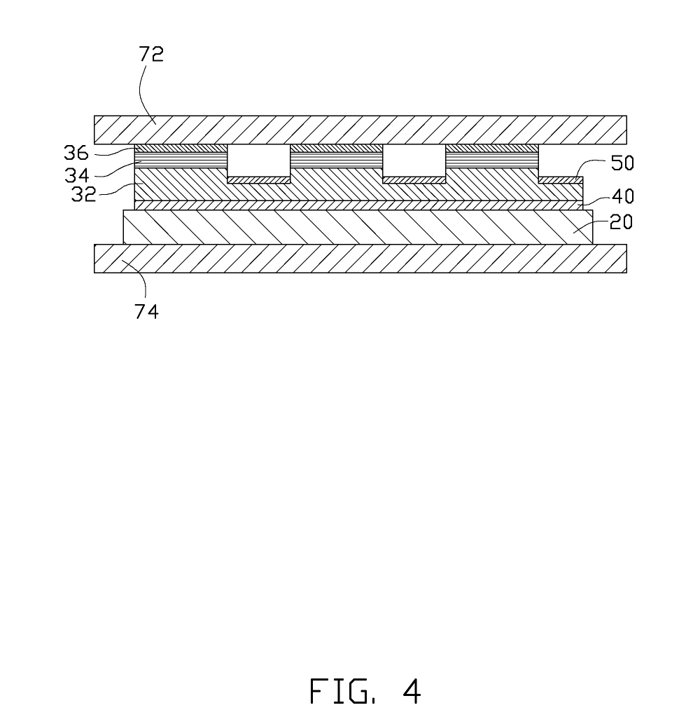

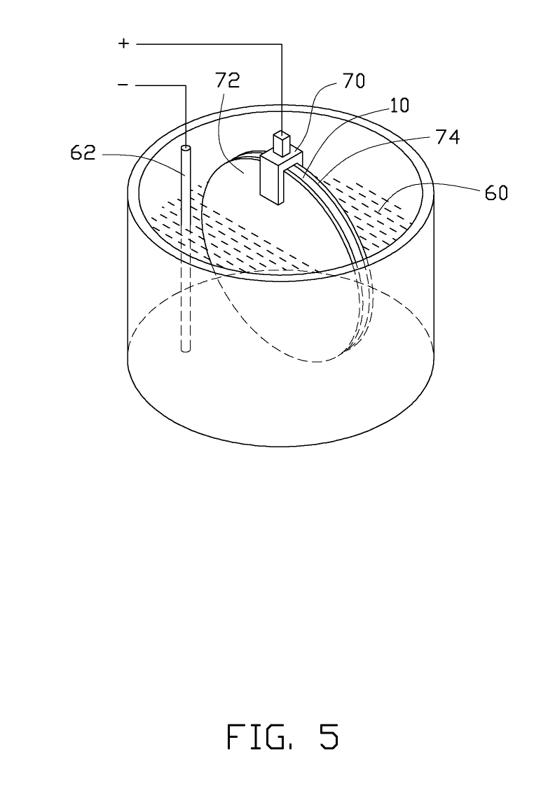

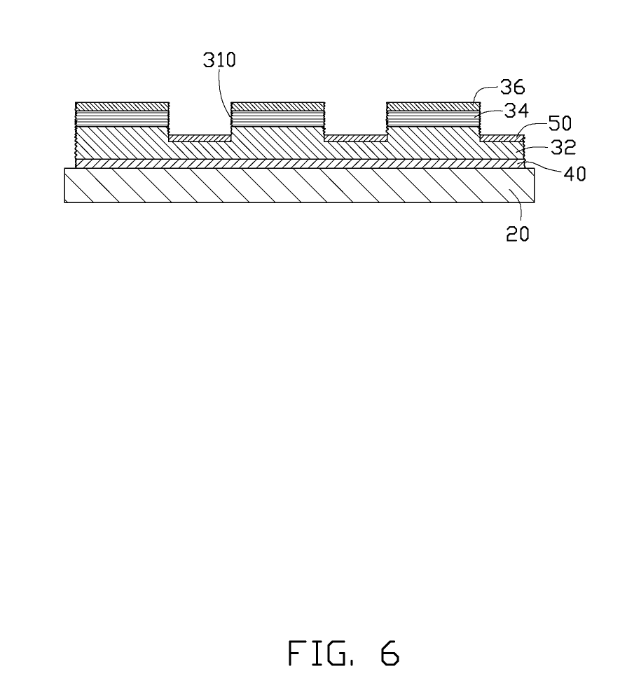

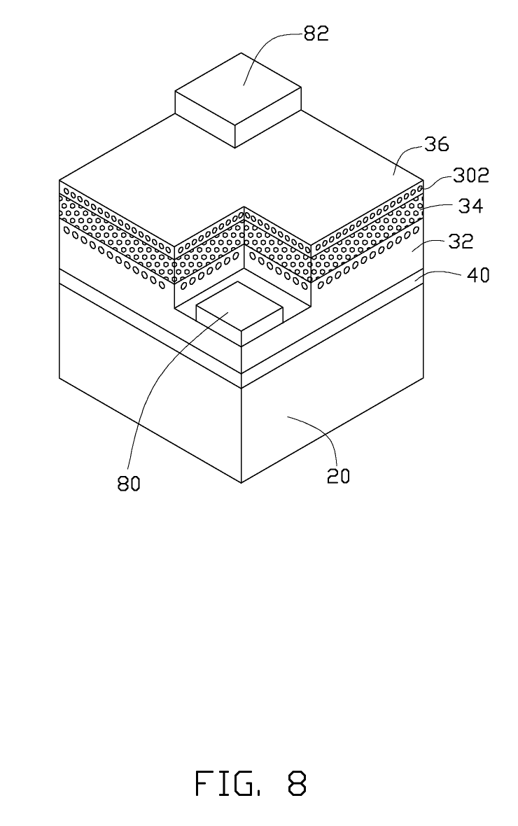

Referring to FIGS. 4-6, the wafer 10 is put into an electrolyte 60 to etch the epitaxial layer 30. The wafer 10 functions as an anode, and a conductive bar 62 made of Pt is inserted in the electrolyte 60 and functions as a cathode. For securing the wafer 10, the wafer 10 is clamped by a fixture 70 before dipped into the electrolyte 60. The fixture 70 includes a first clamping section 72 and a second clamping section 74 spaced from the first clamping section 72. The wafer 10 is sandwiched between the first clamping section 72 and second clamping section 74 with first clamping section 72 abutting against the upper surface of the second semiconductor layer 36 and the second clamping section 74 abutting against the bottom surface of the substrate 20. In this embodiment, the first clamping section 72 acts as a positive electrode, from which a current is capable of being transmitted to the electrolyte 60 through the epitaxial layer 30. When a voltage is applied to the cathode and the anode, the electrolyte 60 is activated by current and etches the epitaxial layer 30. Therefore, a number of holes 302 are formed in lateral surfaces of the epitaxial layer 30, as referring to FIG. 8. A diameter of the holes 302 is configured between 1 nm and 100 nm to reduce totally reflection of light in the lateral surfaces of the epitaxial layer 30, therefore increasing light extraction efficiency of the lighting chip. A depth of the holes 302 can be adjusted by controlling an etching time of the epitaxial layer 30. The longer the epitaxial layer 30 is etched, the deeper the holes 302 are. In addition, a value of the applied voltage and a doping concentration of the epitaxial layer 30 have outstanding effects to the formation of the holes 302. With the increase of the applied voltage or the doping concentration of the epitaxial layer 30, more holes 302 will be formed when the epitaxial layer 30 is etched by the electrolyte 60. However, the value of the applied voltage can not exceed a certain critical value, or else an electro-polishing phenomenon will happen and holes cannot be effectively formed. Besides, the value of the applied voltage can not be too low, or else the electrolyte 60 can not effectively etch the epitaxial layer 30. Preferably, the value of the applied voltage is between 10V and 20V. In this embodiment, the electrolyte 60 is made of oxalic acid, which can effectively react with the epitaxial layer 30 to form holes 302 in the lateral surfaces of the epitaxial layer 30. Because the upper surfaces of the second semiconductor layer 36 and the first semiconductor layer 32 is protected by the first clamping section 72 and the cladding layer 50 respectively, the holes 302 are only formed in the lateral surface of the epitaxial layer 30.

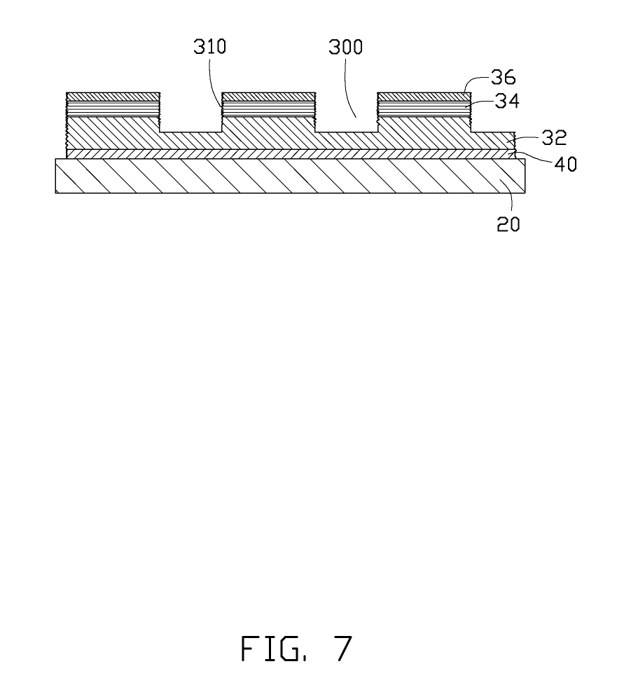

After the etching process, the wafer 10 is taken out from the fixture 70 and cleaned. Referring to FIG. 7, the cladding layer 50 in the grooves 300 is removed to expose the first semiconductor layer 32. Because of the etching of the electrolyte 60, rough surfaces 310 is formed on the lateral sides of each grooves 300. The rough surface 310 extends from the upper surface of the second semiconductor layer 36 to the upper surface of the cladding layer 50.

Referring to FIG. 8, a number of second electrodes 82 and first electrodes 80 are formed on the upper surfaces of the second semiconductor layer 36 and the first semiconductor layer 32 respectively, and then the substrate 20 is cut along the grooves 300 by laser cutting or mechanical cutting, therefore dividing the wafer 10 into a number of individual lighting chips. Because of the covering of the cladding layer 50, the upper surface of the first semiconductor layer 32 remains smooth, and a connection between the first electrode 80 and the first semiconductor layer 32 is strengthened. Similarly, because of the covering of the first clamping section 72, the surface of the second semiconductor layer 36 remains smooth, and a connection between the second electrode 82 and the second semiconductor layer 36 is strengthened. Therefore, a nonuniform current distribution caused by uneven surfaces is prevented. In addition, for distributing current uniformly from the second electrode 82 to the second semiconductor layer 36, a transparent conductive layer (not shown) is previously formed on the upper surface of the second semiconductor layer 36 before the second electrode 82 is formed. The transparent conductive layer can be made of Indium tin oxide (ITO) or Ni/Au alloy permitting transition of the light.

Because a number of holes 302 are formed on the lateral surfaces of the semiconductor lighting chip, the holes 302 can reduce the totally reflection of light in the lateral surfaces of the lighting chip. Therefore, more light will travel to external environment and light extraction efficiency of the semiconductor lighting chip can be improved.

Besides, the electrolyte 60 is made of oxalic acid, which can effectively etch the GaN layer and form a number of holes 302 in the lateral surfaces of the epitaxial layer 30 without a mask. Therefore, the manufacture of the semiconductor lighting chip is relatively simple.

In addition, in the etching by the electrolyte 60, the wafer 10 can be effectively secured by the fixture 70. After the etching is finished, the wafer 10 can be released by loosening the fixture 70. Therefore, the fixture 70 can facilitate the manufacture of semiconductor lighting chip. Besides, in the etching of the epitaxial layer 30, part of the fixture 70 acts as an anode which directly contacts the upper surface of the semiconductor lighting chip. Therefore, the fixture 70 can both conduct current to the wafer 10 and protect the semiconductor lighting chip. The multi-functions fixture 70 has relatively low cost and high reliability.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A method for fabricating a semiconductor lighting chip, comprising steps:
providing a substrate with an epitaxial layer, the epitaxial layer comprising a first semiconductor layer, a second semiconductor layer and an active layer located between the first semiconductor layer and the second semiconductor layer;
dipping the epitaxial layer into an electrolyte to etch surfaces of the epitaxial layer and form a number of holes on the epitaxial layer; and
forming electrodes on the epitaxial layer.

2. The method for fabricating a semiconductor lighting chip of claim 1, wherein the electrolyte is made of oxalic acid.

3. The method for fabricating a semiconductor lighting chip of claim 2, wherein the epitaxial layer is made of GaN.

4. The method for fabricating a semiconductor lighting chip of claim 1, wherein before dipping the epitaxial layer into the electrolyte, a plurality of grooves are formed on the second semiconductor layer to expose part of the first semiconductor layer.

5. The method for fabricating a semiconductor lighting chip of claim 4, wherein after the forming of the grooves, a cladding layer is formed to cover the surface of the first semiconductor layer exposing to external environment.

6. The method for fabricating a semiconductor lighting chip of claim 5, wherein the cladding layer is made of SiO₂.

7. The method for fabricating a semiconductor lighting chip of claim 5, wherein after the epitaxial layer is etched by the electrolyte, the cladding layer is removed and the electrodes are formed on the first semiconductor layer and the second semiconductor layer.

8. The method for fabricating a semiconductor lighting chip of claim 1, wherein the epitaxial layer is secured by a fixture and dipped into the electrolyte.

9. The method for fabricating a semiconductor lighting chip of claim 8, wherein the fixture comprises a first clamping section and a second clamping section, the first clamping section contacts an upper surface of the second semiconductor layer, and the second clamping section contacts an bottom surface of the substrate.

10. The method for fabricating a semiconductor lighting chip of claim 9, wherein the first clamping section acts as an anode.

11. The method for fabricating a semiconductor lighting chip of claim 10, wherein a conductive bar acts as a cathode, a voltage is applied between the first clamping section and the conductive bar for driving a current pass through the electrolyte.

12. The method for fabricating a semiconductor lighting chip of claim 11, wherein the voltage is between 10V and 20V.

13. The method for fabricating a semiconductor lighting chip of claim 1, wherein a buffer layer is formed between the substrate and the epitaxial layer.

14. The method for fabricating a semiconductor lighting chip of claim 1, wherein a diameter of the holes are between 1 nm and 100 nm.

15. A method for fabricating a semiconductor lighting chip, comprising steps:
providing a substrate with an epitaxial layer formed thereon;
providing a fixture to cover a top surface of the epitaxial layer;
etching the epitaxial layer in an electrolyte to form a plurality of holes in lateral surfaces of the epitaxial layer; and
forming electrodes on the epitaxial layer.

16. The method of claim 15, further comprising forming a plurality of grooves in the epitaxial layer before etching the epitaxial layer.

17. The method of claim 16, wherein the epitaxial layer comprises a first semiconductor layer, an active layer, and a second semiconductor layer on the substrate in sequence, and the grooves extend through the active layer and a second semiconductor layer.

18. The method of claim 16, further comprising forming a cladding layer in the grooves before etching the epitaxial layer.
